(19) United States
(12) Patent Application Publication
(10) Pub. No.: US 2025/0358970 A1
(43) Pub. Date: Nov. 20, 2025

(54) TECHNOLOGY FOR DISSIPATING HEAT FROM AN ELECTRICAL CIRCUIT

(71) Applicant: PHOENIX CONTACT GMBH & CO. KG, Blomberg (DE)

(72) Inventor: Frank BEST, Bückeburg (DE)

(21) Appl. No.: 19/100,608

(22) PCT Filed: Jul. 24, 2023
(86) PCT No.: PCT/EP2023/070451

§ 371 Date: Feb. 25, 2025

(30) Foreign Application Priority Data
Aug. 5, 2022 (DE) 10 2022 119 758.1
Dec. 21, 2022 (BE) BE2022/6060

(51) Int. Cl. H05K 7/20

(52) U.S. Cl. CPC H05K 7/2039

(57) ABSTRACT

A device for dissipating heat from an electrical circuit includes: a heat sink having a heat sink base and a plurality of cooling fins extending from the heat sink base for discharging heat; and at least one heat transfer module, which is mechanically and thermally conductively connected or connectable to the heat sink at a first end of the heat transfer module by a press fit and/or a metal integral connection at a joining point of the heat sink, and which has at a second end of the heat transfer module, the second end being at a distance from the first end, a contact surface for making contact with at least one heat discharge point of the electrical circuit so as to absorb the heat from the electrical circuit.

### CROSS-REFERENCE TO PRIOR APPLICATIONS

This application is a U.S. National Phase application under 35 U.S.C. § 371 of International Application No. PCT/EP2023/070451, filed on Jul. 24, 2023, and claims benefit to German Patent Application No. DE 10 2022 119 758.1, filed on Aug. 5, 2022, and to Belgian Patent Application No. BE 2022/6060, filed on Dec. 21, 2022. The International Application was published in German on Feb. 8, 2024 as WO/2024/028146 under PCT Article 21 (2).

### FIELD

The present invention relates to the dissipation of heat from electrical, for example electronic, circuits. A device for dissipating heat, a kit of parts for one or more such devices, an ensemble of various devices, and a method for manufacturing the device are in particular disclosed, without being limited thereto.

### BACKGROUND

Electrical circuits contain heat sources that must be cooled at heat discharge point via heat sinks in order to ensure long-term and reliable functioning of the electrical circuit. The heat usually has to be dissipated indirectly via a heat path with thermal contacts to a heat sink, since the most powerful heat sources, such as power transistors and processors, are spatially distributed throughout the electrical circuit. Therefore, the heat paths must be adapted to each electrical circuit.

To achieve this flexibility, conventional heat paths comprise so-called “heat spreaders”, which have the function of individually conducting heat between the heat discharge point of the electrical circuit and the heat sink. In particular, “heat spreaders” also serve as what are known as distance pieces (in technical terms: “spacers”) between a printed circuit board of the electrical circuit and the heat sink that create space big enough for the height of other components of the electrical circuit.

However, thermally and mechanically connecting conventional “heat spreaders” to the heat sink is associated with disadvantages. The “heat spreaders” are thus usually connected to the heat sink via a housing or by screwing. Such thermal contact points impair the heat conduction process. Even the use of a plastics mass and thermally conductive mass, technically known as “Thermal Interface Material” (TIM), at the contact points cannot increase thermal conduction efficiency to the level of a homogeneous (i.e. integral) casting.

### SUMMARY

In an embodiment, the present invention provides a device for dissipating heat from an electrical circuit, comprising: a heat sink having a heat sink base and a plurality of cooling fins extending from the heat sink base configured to discharge heat; and at least one heat transfer module, which is mechanically and thermally conductively connected or connectable to the heat sink at a first end of the heat transfer module by a press fit and/or a metal integral connection at a joining point of the heat sink, and which has at a second end of the heat transfer module, the second end being at a distance from the first end, a contact surface configured to make contact with at least one heat discharge point of the electrical circuit so as to absorb the heat from the electrical circuit.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 is a schematic sectional view of a conventional heat sink according to a reference example;

FIG. 2 is a schematic sectional view of a device for dissipating heat from an electrical circuit according to a first exemplary embodiment;

FIG. 3 is a schematic side view, looking in parallel with the cooling fins, of a device for dissipating heat from an electrical circuit according to a second exemplary embodiment;

FIG. 4 is a schematic sectional view, looking perpendicularly to the cooling fins, of the device for dissipating heat from an electrical circuit according to the second exemplary embodiment;

FIG. 5 is a schematic side view, looking in parallel with the cooling fins, of a device for dissipating heat from an electrical circuit according to a third exemplary embodiment;

FIG. 6 is a schematic sectional view of a first example of a press fit that can be used in each exemplary embodiment;

FIG. 7 is a schematic sectional view of a third example of a press fit that can be used in each exemplary embodiment;

FIG. 8 is a schematic perspective view of a device for dissipating heat from an electrical circuit according to a fourth exemplary embodiment;

FIG. 9 is a schematic flow diagram of a process for manufacturing an exemplary embodiment of the device; and

FIG. 10A-C are schematic views of a fifth example of a press fit, which can be used in each exemplary embodiment, in different stages of a press-joining process by means of an embodiment of a manufacturing process according to the invention which can be used on further exemplary embodiments of a manufacturing process according to the invention.

### DETAILED DESCRIPTION

In an embodiment, the present invention provides a technology for dissipating heat from an electrical circuit, which makes it possible to use the same heat sinks for different electrical circuits and thereby achieve the same or similar heat conduction efficiency as with a heat sink adapted to the particular electrical circuit.

Exemplary embodiments of the invention, which can be selectively combined with one another, are disclosed below with partial reference to the drawings. In particular, features mentioned within the context of the device can also be accordingly implemented in the method, for example by a step of providing the corresponding feature or by a step of executing a function of the device. Furthermore, the device may comprise any of the features mentioned within the context of the method and may be configured to perform any step mentioned within the context of the method.

A first aspect relates to a device for dissipating heat from an electrical circuit. The device comprises a heat sink. The heat sink comprises a heat sink base and a plurality of cooling fins, which extend from the heat sink base, for discharging heat. The device further comprises at least one heat transfer module. The at least one heat transfer module is mechanically and thermally conductively connected or connectable to the heat sink at a first end of the heat transfer module by means of a press fit and/or a metal integral connection at a joining point of the heat sink. Furthermore, the at least one heat transfer module has, at a second end of the heat transfer module, the second end being at a distance from the first end, a contact surface which is designed to make contact with at least one heat discharge point of the electrical circuit to absorb the heat from the electrical circuit.

The technology allows, proceeding from a (for example, generic) heat sink, for a device for dissipating heat that is adapted to the electrical circuit. Exemplary embodiments of the device can absorb the heat from the electrical circuit via the at least one heat transfer module at the second end, which module is adapted to the at least one heat discharge point of the electrical circuit. The at least one heat transfer module and/or the heat sink, in particular its heat sink base, can also serve to distribute the heat (heat spreading).

The electrical circuit may comprise electrically interconnected (e.g. electronic) components. The components can be arranged in one or more modules or on one or more circuit carriers. The components may comprise linear components (e.g. resistors, capacitors or inductors) and non-linear components (e.g. transistors), including electromechanical components (e.g. relays or solenoid valves).

In each exemplary embodiment, the press fit and/or the metal integral connection can allow for a thermal (specifically thermally conductive) and mechanical connection to the heat sink. The thermally conductive connection can be an integral one-piece connection due to the metal integral connection or, after making the press fit, can be as effective as if the heat sink and heat transfer module were integral and one piece. This means that the device can be comparable to a device made from a block in terms of heat transfer. Likewise, the production is modular for easy variant creation. For example, due to the press fit and/or the metal integral connection, surfaces at the first end that are in contact with the heat sink can have a degree of thermal resistance that substantially corresponds to an integral one-piece component.

A press fit profile (also: first profile of the press fit) at the first end of the heat transfer module may comprise projecting surfaces and transverse surfaces. The projecting surfaces may be convex and/or longitudinal surfaces and/or extend as an extension of the distance between the second end and the first end (i.e. of a longitudinal direction of the heat transfer module).

The transverse surfaces may be surfaces next to and/or between the projecting surfaces and/or extend transversely (e.g. perpendicularly) to the longitudinal direction.

The heat sink can have a press-fit profile (also: second profile of the press fit) at the joining point, which profile complements the first profile, for example their shapes are coordinated with and/or correspond to one another, at least in portions, for the creation of a press fit. For example, the second profile may have projecting surfaces and transverse surfaces that are complementary to the projecting surfaces and the transverse surfaces of the first profile, respectively.

By means of the press fit, heat can be dissipated to the heat sink via both the projecting surfaces and the transverse surfaces. Alternatively or additionally, the metal integral connection can eliminate the need for the projecting surfaces and/or the transverse surfaces as interfaces between the heat transfer module and the heat sink. In each exemplary embodiment, the fundamental effect of the heat transfer resistances between the contact surfaces can be minimized, which is achieved by the metal integral connection (indicated, for example, by the press fit) or which the press fit renders at least substantially equivalent to an integral connection.

The heat absorbed at the contact surface and/or dissipated at the cooling fins (more precisely: the amount of heat) may be some (for example a fraction) of the heat generated by the electrical circuit (i.e. of the amount of heat).

The cooling fins may comprise (for example thin-walled) lamellae or (at least some of them) may be designed as such.

The heat transfer module can be a heat distributor. Accordingly, this can be referred to in technical terms as a “heat spreader”, “heat spreader module”, “modular heat spreader” or “modular heat spreader-spacer combination”. The at least one heat discharge point can comprise at least one heat center (technical term: “hotspot”) of the electrical circuit.

The at least one heat discharge point of the electrical circuit may comprise a heat discharge point of an electronic component (for example a power transistor, an integrated circuit or a processor). Alternatively or additionally, the at least one heat discharge point of the electrical circuit can comprise a heat collection point on a circuit carrier (for example on a printed circuit board). The heat collection point can dissipate the heat from a plurality of components of the electrical circuit (for example via copper surfaces or conductor tracks of the electrical circuit).

The press fit can be a force fit (also: compression). Alternatively or additionally, the press fit can be an interference fit, for example joined in the form of an external (concave) press fit profile temporarily widened by thermal expansion. Alternatively or additionally, the press fit can be joined by re-pressing, for example by re-pressing a metal filler material which preferably corresponds to the material of the heat transfer module and/or the heat sink.

The metal integral connection can be an integral connection between metals (for example a first metal of the heat transfer module and the first metal or a second metal of the heat sink) or alloys. Alternatively or additionally, the metal integral connection can be provided at the joining point without the use of additional materials.

The second end can also be referred to as the warm end and the first end can accordingly be referred to as the cold or cool end. Alternatively or additionally, the first end can be referred to as the free end or joining end.

In each exemplary embodiment, the joining point (for example of one of the at least one heat transfer module) can be arranged on the heat sink base or on one of the cooling fins.

The arrangement of at least one joining point on the heat sink base can allow for a compact combination of the electrical circuit and the device, for example by arranging components of the electrical circuit between the cooling fins (for example resting against the adjacent cooling fins or free-standing in the space therebetween).

Alternatively or additionally, the arrangement of at least one joining point on one of the cooling fins can reduce the length of the heat path between the contact surface and the joining point via the heat transfer module (for example, compared to a joining point on the heat sink base). This can be advantageous, for example, if the heat discharge point (e.g. a heat source) of the electrical circuit is in the immediate vicinity of a cooling fin. Alternatively or additionally, the cooling fin comprising a joining point can advantageously dissipate the heat to the environment without having to go via the heat sink base.

Alternatively or additionally, the arrangement of at least one joining point on an outer side of one of the outer cooling fins of the heat sink can thermally connect a component (or plurality of components) of the electrical circuit to the heat sink, for example even if the component is arranged next to the heat sink, i.e. is not covered by the cooling surface or the heat sink base. This allows the electrical circuit (for example a circuit carrier of the electrical circuit) to have a larger surface area than the heat sink (for example than the heat sink base).

Due to the modular combination of the heat sink with the at least one heat transfer module, the same heat sinks can be adapted for different electrical circuits. The press fit and/or the metal integral connection can achieve a mechanical and thermal connection between the heat transfer module and the heat sink that is equal or similar to an integral one-piece device (for example, in comparison with a device manufactured by molding or forming processes that was created from an originally one-piece main body). This condition can be achieved by joining (i.e. the press-fit and/or metal integral connection).

Joining (i.e. the press-fitting and/or metal integral connection of) the at least one heat transfer module to the heat sink allows for a simple, cost-effective, individually positionable and robust thermal connection (e.g. the function of a thermal bridge) of the contacted heat discharge point and/or creates installation space for components between the heat sink base and the circuit carrier (e.g. the function of a distance piece) without significantly impairing heat conduction efficiency in comparison with an individually adapted heat sink milled from one piece.

The same or other exemplary embodiments of the device enable components to be mounted on the circuit carrier between the circuit carrier and the heat sink base and/or thermal contact, even outside the heat sink base. The latter allows for an efficient circuit diagram of the electrical circuit, for example an efficient layout of the circuit carrier (for example the printed circuit board). The exemplary embodiments mentioned first can allow components (also: parts) to be mounted below the heat sink, the height of which is greater than the heat discharge point (also known in technical terms as “heat spot” or “hot spot”) to be connected via the heat transfer module. This means that the heat sink or its cooling base covers the component that is facing the heat sink.

Thus, the at least one joining point can be advantageously usable for installation positions below the heat sink on the heat sink base and/or (particularly advantageous in the second exemplary embodiment mentioned in the previous paragraph) can be formed on the cooling fins, for example for a lateral or frontal contact direction. Thus, exemplary embodiments can enable a thermal connection between a heat discharge point of the electrical circuit located laterally outside the heat sink and the heat sink.

Numerous geometric variations are possible for profiles of the press fit. Examples of joining principles are press fitting (especially interference fitting) and/or re-pressing material during or after joining.

Due to the press fit and/or the metal integral connection, no thermal interface material (TIM for short) is required in the thermal contact path. This lowers the material costs of the device and eliminates application costs.

The press fit or the metal integral connection can reduce the thermal resistance in the thermal path.

Due to efficient heat dissipation, the device can contribute to a longer service life (e.g. functional life) of the components of the electrical circuit.

Exemplary embodiments of the device can eliminate sources of error during assembly, such as loose thermal contacts, as a result of the mechanically robust connection (for example, a connection whose mechanical load limit is determined by the heat transfer module itself and not by the joining process).

Because the device can be assembled as an assembly, separate joining elements are no longer required, which simplifies assembly, saves on material and results in lower application costs (e.g. TIM only on the contact surfaces of the second ends). Additional holders in a housing for positioning loose distance pieces (spacers) and loose heat distributors (heat spreaders) can be omitted, reducing the space required in the housing.

Due to the press fit or the metal integral connection, exemplary embodiments of the device can be mechanically robust, simple and individually positionable.

Assembly is less prone to errors. Joining contours (i.e. joining geometries and press-fit profiles) can be created during a preliminary molding manufacturing method and/or separation manufacturing method and thus involve virtually no additional effort. Furthermore, these elements are captively held on the heat sink (in contrast to a screw connection, for example).

The press fit can be used as a joining technique for mechanically reliably and thermally efficiently connecting the functional combination of the heat spreader and spacer with the heat sink to form a compact assembly, in particular without the need for additional connection materials/means.

The device may further comprise a housing in which the electrical circuit is arranged. The cooling fins of the heat sink may be exposed outside the housing. Alternatively or additionally, the at least one heat transfer module can be arranged at least partially or completely within the housing.

The heat sink can form an outer wall of the housing. Alternatively or additionally, the heat transfer module can transfer the heat from the electrical circuit from a region of the electrical circuit housing that is inaccessible to cooling or circulating air to the heat sink. For example, the at least one heat transfer module may not comprise any cooling fins (for example lamellae) and/or may be optimized for transporting heat from the heat source to the heat sink, whereby it quickly transports the heat further and is preferably designed without cooling fins. Alternatively or additionally, the heat transfer module can be an active or passive thermal bridge.

The press fit can comprise the metal integral connection (at least in portions, in particular partially or at points). The integral connection can be achieved by cold welding, extrusion and/or friction during press-fitting.

The press fit between the heat transfer module and the heat sink can be joined by a transverse translational movement (transverse movement). For example, during press fitting, the transverse surfaces may flow or melt on the surface due to shear forces and/or the transverse movement. Alternatively or additionally, the press fit between the heat transfer module and the heat sink can be joined by a longitudinal translational movement (longitudinal movement). For example, during press fitting, the longitudinal surfaces may flow or melt on the surface due to shear forces and/or the longitudinal movement. In both cases, the metal integral connection between the heat transfer module and the heat sink can thus be produced at least partially at the first end.

The metal integral connection can be a welded connection between a metal of the heat transfer module and a metal of the heat sink. The metal of the heat transfer module and the metal of the heat sink can be the same metal. Alternatively or additionally, the metal integral connection can be an alloy of the metal of the heat transfer module and the metal of the heat sink. For example, the metal integral connection does not comprise a third component that differs from the metal of the heat transfer module and the metal of the heat sink. Advantageously, joining can be carried out without any auxiliary material and/or without the supply of additional energy (see arc welding below).

The metal integral connection may comprise an arc welded joint. The metal integral connection (i.e. the arc welded joint) can be made by electrode welding (i.e. arc welding).

The heat transfer module can be welded on at the first end without a form fit and/or flat at the (for example, also flat) joining point by arc welding.

Alternatively or additionally, a current for heating can be applied between the heat sink and the heat transfer module during pressing so that the first end of the heat transfer module flows into a recess (for example as a die at the joining point) in the heat sink by drop forging or extrusion. As a result of heating (for example by melting) and/or drop forging or extrusion, air inclusions that would remain in a conventional press fit can be eliminated.

The press fit can have the metal integral connection by inductively heating the first end. For example, before, during or after making the press fit, an inductor (e.g. a water-cooled induction coil) can be placed around the heat transfer module (e.g. in the longitudinal direction) for inductively heating the first end of the heat transfer module.

Through this energy input—or through extrusion alone—macroscopic or microscopic air inclusions between the heat transfer module and the heat sink can be melted. The thermally conductive connection between the heat transfer module and the heat sink can be homogeneous without any gaps.

The joining point can comprise two adjacent cooling fins. The press fit may comprise a friction fit and/or a metal integral connection between the heat transfer module and at least one of the cooling fins (or between the two adjacent cooling fins) of the heat sink. For example, the press fit may be created by the heat transfer module at the first end being larger than a distance between the adjacent cooling fins. The heat transfer module can be pressed between the two adjacent cooling fins. Pressing (pushing in) can be carried out lengthwise or crosswise.

Alternatively or additionally, a contour of the cooling fins can increase the surface area of the heat sink compared to a flat surface for exchanging heat with the environment. This contour of the cooling fins can also be a press fit profile (also: second profile of the press fit) in the form of a (potential) joining point for the press fit.

Alternatively or additionally, the cooling fins may be a press-fit profile (i.e. the second profile of the press fit that complements the first profile). Where no heat transfer module is press-fitted (i.e. joined) to the heat sink, the press-fit profile can increase the surface area of the heat sink for exchanging heat with the environment (i.e. function as cooling fins of the heat sink). Where a heat transfer module is press-fitted (i.e. joined) to the heat sink, the press-fit profile can allow for the press fit with the heat transfer module.

The at least one heat transfer module can have a first profile of the press fit at the first end. The heat sink can have a second profile that is (for example partially) complementary to the first profile at each joining point. For example, the heat sink can have one or more additional joining points comprising the second profile so as to allow for variants during production.

The one or more additional joining points may not be joined. This means that the heat sink can have an excess of joining points (for example during production before press fitting). During the manufacture of the device, the heat sink can have a plurality of joining points with the second profile so that one of the at least one heat transfer modules is connected to one of the plurality of joining points each time in a manner adapted to the electrical circuit (for example the geometry, position and/or number of the at least one heat discharge point of the electrical circuit).

The first profile and the second profile can interlock or flow into one another in the press fit without leaving any gaps. Connecting them without any gaps or with only a few gaps can increase heat transfer efficiency, for example compared to conventional thermal joining using TIM.

The connection partners of the press fit can interlock or flow into one another over their entire surface without any gaps (for example for the metal integral connection).

For example, the first profile and the second profile shapes are designed to correspond in such a way that at least portions of the first profile are received in the second profile after joining. The second profile is in particular a recess in the heat sink, with the advantage that the surface for the arrangement is thus unaffected. Optionally, a volume (e.g. a material volume) of the first profile corresponds to a volume (e.g. a cavity volume) of the second profile or is slightly larger than the volume of the second profile in order to exclude the formation of air inclusions at the connection between the heat sink and the heat transfer module by means of plastic deformation (e.g. extrusion) during press fitting. This can reduce thermal resistance.

The second end may be opposite the first end of at least one of the at least one heat transfer modules. Alternatively or additionally, at least one heat transfer module of the at least one heat transfer modules can extend in a longitudinal direction from the second end to the first end and/or be arranged transversely (preferably perpendicularly) to the surface of the first end. Between the first end and the second end, a further contact surface can be arranged laterally to the longitudinal direction (for example in parallel with the longitudinal direction). Alternatively or additionally, the at least one heat transfer module can have a plurality of contact surfaces for absorbing the heat.

For example, a first contact surface can be arranged at the second end that is opposite the first end in the longitudinal direction and/or transversely, in particular perpendicularly, to the longitudinal direction. Alternatively or additionally, a second contact surface may be offset sideways (i.e. laterally) with respect to the longitudinal direction and/or in parallel with the longitudinal direction.

The heat sink can be designed independently of the electrical circuit. Alternatively or additionally, the at least one heat transfer module can be connected to the heat sink and/or shaped depending on the topography of the at least one heat discharge point of the electrical circuit.

The (for example generic) heat sink can be adapted to the topography of the at least one heat discharge point of the electrical circuit via the at least one heat transfer module (having, for example, a modular design). Despite the thermally conductive connection, the heat sink can thus be kept at a distance from the electrical circuit in order to rule out a collision. Alternatively or additionally, the at least one heat transfer module can come into contact with heat discharge points for absorbing the heat of the electrical circuit that are distributed by means of the shape (for example at the second end) and/or length (for example in the longitudinal direction) of the at least one heat transfer module (for example on the circuit carrier) and/or have different orientations.

The device can comprise a plurality of heat transfer modules. The heat transfer modules can each extend from the heat sink with different lengths between the first end and the second end (for example in parallel with one another). The different lengths can correspond to the topography of the heat discharge points of the electrical circuit (for example, the heights of components of the electrical circuit on the circuit carrier). The different lengths can complement a topography of the at least one heat discharge point of the electrical circuit. Alternatively or additionally, the different lengths can correspond to the distances between the heat sink base and the relevant heat discharge surface.

Due to the shape and/or length of the heat transfer modules, heat discharge points for absorbing the heat from the electrical circuit, which points are distributed and/or have different orientations, can be contacted or contactable.

The heat sink may comprise aluminum or copper or an alloy (e.g. comprising aluminum and copper). Alternatively or additionally, the at least one heat transfer module may comprise copper or aluminum or an alloy (for example comprising aluminum and copper).

Due to the high degree of thermal conductivity of copper, heat conduction paths to the heat sink of different lengths can be thermally balanced. Due to the low density of aluminum, the overall weight of the device can be low.

A component can be arranged on the circuit carrier (for example on the printed circuit board) between the circuit carrier (for example the printed circuit board) and the heat sink base of the heat sink and/or next to the at least one heat transfer module, which component is higher in the direction of the heat sink than the heat discharge point contacted via the heat transfer module. For example, a component that is thermally connected via the heat transfer module can be smaller than the component arranged (i.e., mounted) between the heat sink base and the circuit carrier and/or next to the at least one heat transfer module on the circuit carrier.

In each exemplary embodiment, preferably the circuit carrier (e.g., the printed circuit board) is parallel to the heat sink base when or after the heat sink is arranged thereon.

The heat sink and/or the at least one heat transfer module can be filled with a fluid. For example, the at least one heat transfer module may comprise a heat pipe from the second end to the first end, which is parallel to the heat flow or a longitudinal direction of the heat transfer module. For example, a boiling point of an operating medium hermetically enclosed in the heat pipe can be adapted to the temperature at the first end of the heat transfer module and a condensation point of the operating medium can be adapted to the temperature at the second end of the heat transfer module.

The heat pipe can further reduce the overall thermal resistance of the combination of the heat transfer module and heat sink. For example, the overall thermal resistance may be smaller than that of an integral one-piece component having the corresponding shape of the heat transfer module and the heat sink combined.

The operating medium can be a refrigerant. Alternatively or additionally, in order to minimize the thermal resistance, a material of the operating medium and/or a pressure of the operating medium can be selected such that the boiling point of the operating medium at the second end is only slightly above, and/or at the first end only slightly below, the boiling point of the operating medium.

As an exemplary embodiment of the heat pipe, the heat transfer module can have a hole in the longitudinal direction at the first end, which is filled with the operating medium and is sealed in a gas-tight manner by the press fit.

A second aspect of the technology relates to a system comprising an electrical circuit (for example a circuit carrier with the electrical circuit) and to a device for dissipating heat from the electrical circuit according to the first aspect. The contact surface (or contact surfaces) of the at least one heat transfer module can contact the at least one heat discharge point of the electrical circuit for absorbing the heat of the electrical circuit.

In every aspect, the circuit carrier comprising the electrical circuit can be a so-called “System on a Module” (SOM board).

The system may have any of the features mentioned in connection with the device aspect. For example, the at least one heat transfer module can be adapted to a topography of the at least one heat discharge point of the electrical circuit.

A third aspect of the technology relates to an ensemble of devices for dissipating heat from an electrical circuit according to the first aspect, wherein the devices of the ensemble have the same heat sink and differ in that the at least one heat transfer module is mechanically and thermally conductively connected to the heat sink at different joining points of the heat sink, and/or in that the at least one heat transfer module has different lengths between the first end and the second end.

Advantageously, the same heat sink can be used for different electrical circuits.

A fourth aspect of the technology relates to a kit of parts for a device for dissipating heat from an electrical circuit according to the first aspect or for an ensemble according to the third aspect. The kit of parts comprises one or more identical heat sinks having a heat sink base and a plurality of cooling fins extending from the heat sink base for discharging heat. Furthermore, the kit of parts comprises a plurality of heat transfer modules, each of which are mechanically and thermally conductively connectable to the heat sink at a first end of the heat transfer module by means of a press fit and/or metal integral connection at a joining point of the heat sink, and each of which has at a second end of the heat transfer module, the second end being at a distance from the first end, a contact surface which is designed to make contact with at least one heat discharge point of the electrical circuit to absorb the heat from the electrical circuit, wherein the plurality of heat transfer modules have different lengths between the first end and the second end.

Advantageously, the kit of parts can allow for a modular construction of the device that is adapted to the electrical circuits.

A fifth aspect of the technology relates to a method for manufacturing a device for dissipating heat from an electrical circuit. The method comprises a step of providing a heat sink having a heat sink base and a plurality of cooling fins, which extend from the heat sink base, for discharging heat.

The method further comprises a step of press-joining and/or joining at least one heat transfer module with a first end of the heat transfer module by means of a metal integral connection at a joining point of the heat sink for mechanically and thermally conductively connecting it to the heat sink.

The method further comprises a step of bringing the at least one heat transfer module into contact with a contact surface arranged at a second end of the heat transfer module that is at a distance from the first end at at least one heat discharge point of the electrical circuit to absorb the heat from the electrical circuit.

The press-fitting step means creating a press fit. Alternatively or additionally, joining by means of a metal integral connection means the creation of a metal integral connection. Preferably, joining by means of a metal integral connection is carried out by cold welding without the additional introduction of process heat.

The heat sink can have a plurality of joining points. Joining (i.e., press-joining and/or joining by means of a metal integral connection) may involve selecting the joining point from the plurality of joining points depending on (e.g., the topography of) the electrical circuit.

The method may further comprise a step of shortening, optionally milling, the at least one heat transfer module at the second end depending on the electrical circuit. For example, shortening is carried out after joining (i.e. after press-joining and/or after joining by means of a metal integral connection).

For example, a plurality of heat transfer modules (after joining the plurality of heat transfer modules to the heat sink) can be shortened in one process (e.g., in a milling process) depending on (e.g., the topography of) the electrical circuit.

One advantage of shortening is the ability to fine-tune the dimensions with respect to any previous adjustment, which allows for greater dimensional accuracy. Due to the mechanical connection of the heat transfer modules via the heat sink that already exists during the shortening process, the heat transfer modules can be shortened precisely according to (e.g. the topography of) the heat discharge points of the electrical circuit.

Providing the heat sink may involve extruding (e.g., extrusion molding) the heat sink, for example including the heat sink base and the cooling fins and/or including the one or more joining points (i.e., the second profile).

The method may further involve providing (e.g. extruding, preferably extrusion molding) the at least one heat transfer module, for example including the first profile at the first end for press fitting and/or including the contact surface at the second end, which is designed to contact a heat discharge point of the electrical circuit in order to absorb the heat from the electrical circuit.

Herein, features shown or described in different embodiments with the same reference signs are interchangeable.

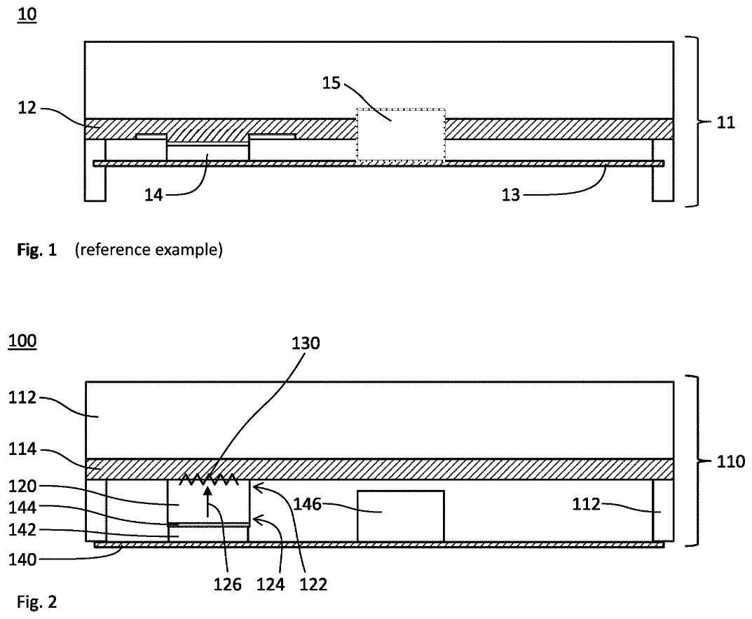

FIG. 1 shows a reference example. The thermal connection between a component 14 and a base 12 of a heat sink 11 determines the distance between the printed circuit board 13 and the base 12. This excludes the possibility of accommodating another taller component 14 beneath the heat sink on the printed circuit board 13.

FIG. 2 is a schematic sectional view of a first exemplary embodiment of the device for dissipating heat from an electrical (for example electronic) circuit, which device is generally designated by reference sign 100.

The device 100 comprises a heat sink 110 having a heat sink base 114 and a plurality of cooling fins 112 extending from the heat sink base for discharging heat.

Furthermore, the device 100 comprises at least one heat transfer module 120. Each heat transfer module 120 is mechanically and thermally conductively connected to the heat sink 110 at a first end 122 of the heat transfer module 120 by means of a press fit 130 and/or metal integral connection at a joining point of the heat sink 110. Each heat transfer module 120 has at a second end 124 of the heat transfer module 120, the second end being at a distance from the first end 122, a contact surface 144 which is designed to make contact with at least one heat discharge point 142 of the electrical circuit to absorb the heat from the electrical circuit.

Due to the press fit 130 and/or the metal integral connection, a heat flow can flow in the direction 126 as efficiently as if the heat transfer module 120 and the heat sink 110 were integrally formed in one piece (for example, a metal casting or milled from a workpiece).

In contrast to the direct thermal connection shown in FIG. 1, exemplary embodiments of the device 100 enable the combined function as a heat spreader and spacer, i.e. for thermal distance bridging, if the heat discharge point 142 of the electrical circuit is flatter than other components on a circuit carrier 140 (for example a printed circuit board 140) of the electrical circuit below the heat sink.

Between the printed circuit board 140 and the heat sink base 114 of the heat sink 110 and/or next to the at least one heat transfer module 120, a component 146 is arranged on the printed circuit board 140, which is higher in the direction 126 toward the heat sink 110 than the heat discharge point 142 or heat discharge points 142 contacted via a heat transfer module 120.

The modularity of the device 100, i.e. the use of a heat sink 110 for different electrical circuits with different heat discharge points 142, exists as a result of the freedom of choice (for example with regard to the joining point and shape of the at least one heat transfer module) when joining the heat sink 110 to the heat transfer module 120 or the plurality of heat transfer modules 120. This modularity is achieved without separate joining elements (such as screw and/or spring connections), which traditionally require additional assembly steps and increase thermal resistance, since screwed or spring-loaded contact surfaces are, on a molecular level, only partially in contact for conducting heat.

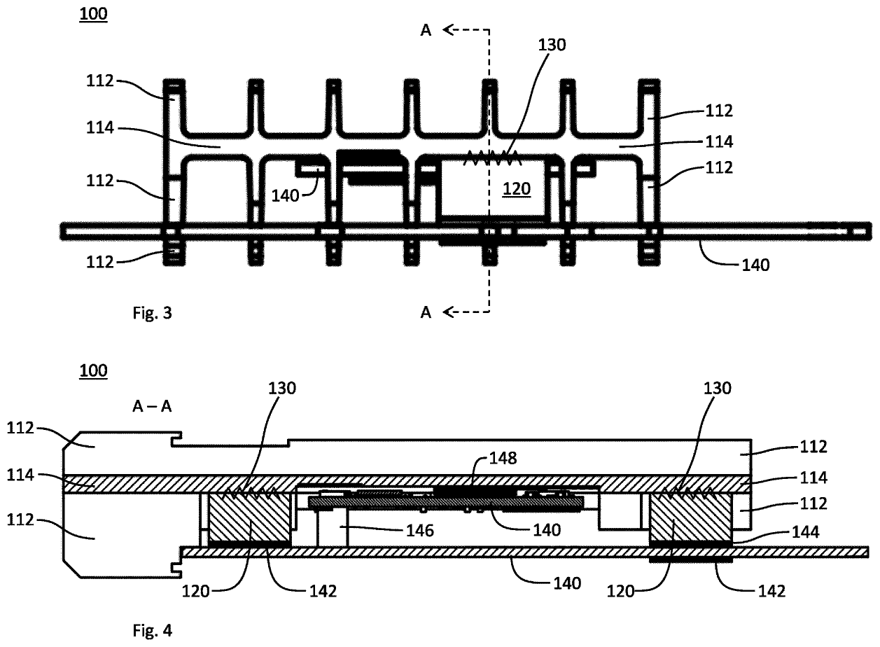

FIG. 3 is a schematic side view (viewed in parallel with the cooling fins 112) of a device 100 for dissipating heat from an electrical circuit according to a second exemplary embodiment.

Owing to the heat transfer modules 120, the electrical circuit can comprise two parallel printed circuit boards 140. For example, the heat transfer modules 120 allow the electrical circuit to have a spatial structure with a plurality of levels. An (upper) first printed circuit board 140 comprises components 148 that directly contact the heat sink base 114 in a conventional manner. A (lower) second printed circuit board 140 comprises components which are thermally coupled to the heat sink 110 as a heat discharge point 142 via at least one heat transfer module 120.

FIG. 4 is a schematic sectional view of the exemplary embodiment of FIG. 3 along the section line A-A. Optionally, the second printed circuit board 140 can comprise at least one component 146 which is arranged in the space created by the heat transfer modules 120. For example, the second printed circuit board 140 is larger than the first printed circuit board 140. The component 146 is arranged on the second printed circuit board 140 outside the first printed circuit board and extends beyond the plane of the first printed circuit board 140.

In the exemplary embodiments described above, the heat transfer module 120 or the heat transfer modules 120 is/are joined to the heat sink base 114 for thermally contacting the heat discharge points 142 of components below the heat sink base 114 and/or between the cooling fins 112.

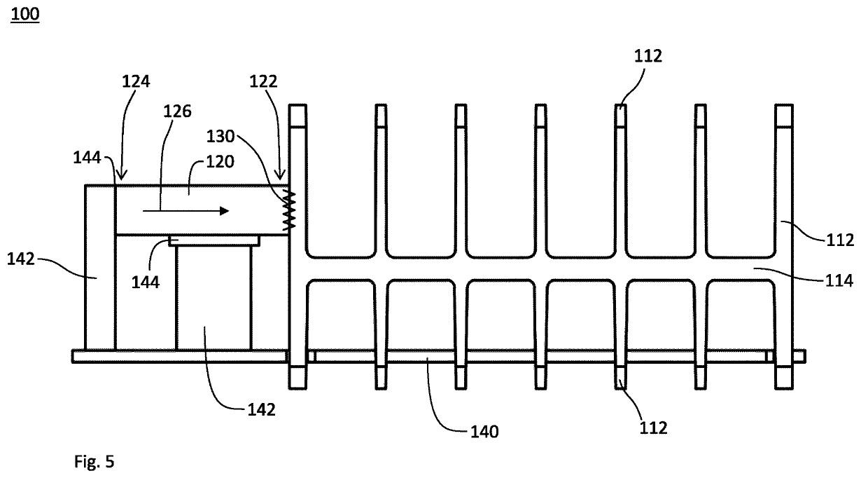

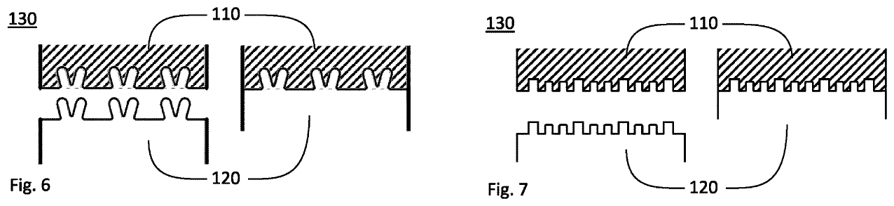

In a third exemplary embodiment of the device 100 shown schematically in FIG. 5, at least one heat transfer module 120 is joined to an edge cooling fin 112 for thermally contacting heat discharge points 142 (i.e. components) which are arranged beside the heat sink 110 on the printed circuit board 140.

This lateral coupling between components and a cooling fin 112 can be combined with any of the above-described ways in which components are coupled to the heat sink base 114.

Alternatively or additionally, as shown schematically in the context of the third exemplary embodiment in FIG. 5, a plurality of heat discharge points 142 (e.g. a plurality of components) of the electrical circuit can be coupled to one heat transfer module 120.

The first end 122 and the second end 124 are opposite one another in the longitudinal direction 126 of the heat transfer module 120. In at least one heat transfer module 120, a further contact surface 144 is arranged laterally with respect to the longitudinal direction 126 (for example in parallel with the longitudinal direction 126).

Thus, a first contact surface 144 (for example perpendicular to the longitudinal direction 126) can be arranged at the second end 124 of the heat transfer module 120 that is opposite the first end 122 in the longitudinal direction 126. In addition, a second contact surface 144 (for example parallel to the longitudinal direction) can be arranged on the heat transfer module 120 so as to be offset sideways (i.e. laterally) from the longitudinal direction 126.

FIGS. 6 and 7 are schematic sectional views of examples of the press fit that can be used in each exemplary embodiment of the device 100. The left half of the image shows the state before joining and the right half of the image shows the joined state of the heat sink 110 and the heat transfer module 120.

The first end of the heat transfer module 120 comprises a first profile of the press fit. The joining point of the heat sink 110 comprises a complementary second profile of the press fit. While in the examples shown the first profile is convex and the second profile is concave, in each exemplary embodiment the first and second profiles can also be swapped around.

Each example comprises transverse surfaces at the first end of the heat transfer module 120 that is perpendicular to the longitudinal direction (which is the vertical direction in the plane of the illustration).

The first example of the first profile shown in FIG. 6 comprises V-shaped longitudinal surfaces. The joining process may involve a transverse movement perpendicularly to the longitudinal direction, in which the first profile is inserted laterally into the second profile and moved along the heat sink 110 to the desired joining point.

Optionally, any frictional heat that occurs can heat up or even melt the surfaces, creating the metal integral connection in portions.

Alternatively or additionally, in each exemplary embodiment and/or for each profile shape, following the form-fitting and/or frictional joining process, the first end of the heat transfer module 120 and/or the joining point of the heat sink 110 can be inductively heated. By tempering, i.e. heating to a tempering temperature (for example of at least 500 degrees Celsius), creep (i.e. viscoelastic or plastic deformation) of the metal heat transfer module 120 at the first end and/or of the heat sink 110 at the joining point can be induced or accelerated so that the effective exchange surface area for heat conduction at a molecular level is significantly increased or air inclusions are reduced or eliminated.

Alternatively or additionally, in each exemplary embodiment and/or for each profile shape, following the form-fitting and/or frictional joining process, the first end of the heat transfer module 120 and/or the joining point of the heat sink 110 can be inductively melted for the metal integral connection.

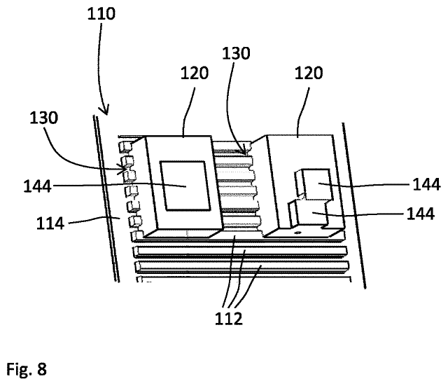

The second example of the first profile shown in FIG. 8 comprises rectangular profiles as longitudinal surfaces. The joining process may involve a longitudinal movement in the longitudinal direction. The profiles can be secured against laterally offset joining (for example by means of rectangular profiles of different widths and/or depths).

FIG. 8 is a schematic perspective view of the device 100 according to a fourth exemplary embodiment, in which the cooling fins 112 also function as a press-fit profile (i.e. as the heat sink-side “second” profile of the press fit). As a result, the joining point can be freely selected over a large surface area of the heat sink 110 (for example, on the grid of the cooling fins 112).

Where no heat transfer module 120 is joined, the cooling fins 112 continue to dissipate heat to the environment.

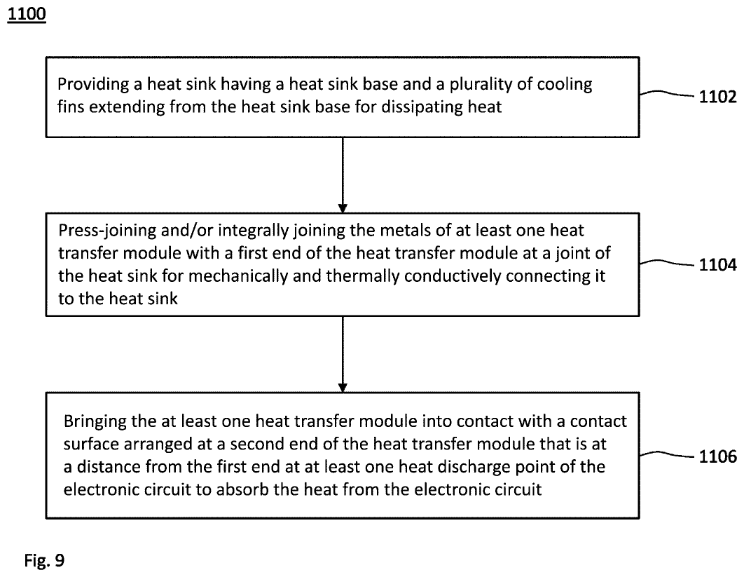

FIG. 9 is a schematic flow diagram of a method 1100 for producing a device (for example, an exemplary embodiment of the device 100 disclosed herein) for dissipating heat from an electrical circuit.

In a step 1102, a heat sink 110 is provided that has a heat sink base 114 and a plurality of cooling fins 112 extending from the heat sink base for discharging heat.

In a step 1104, a mechanical and thermally conductive connection to the heat sink 110 is produced by press-fitting and/or joining at least one heat transfer module 120 to a first end 122 of the heat transfer module 120 at a joining point of the heat sink 110 by means of a metal integral connection.

In a step 1106, the at least one heat transfer module 120 comes into contact with at least one heat discharge point 142 of the electrical circuit by means of a contact surface 144 arranged at a second end 124 of the heat transfer module 120 that is spaced apart from the first end 122 in order to absorb the heat from the electrical circuit

The method may comprise any of the steps described above within the context of the device 100. For example, joining by means of a metal integral connection may involve arc welding. As an alternative or in addition to press-joining, joining by means of a metal integral connection can be achieved by inductive heating.

The heat sink can have a plurality of joining points. Joining (i.e. press-joining and/or joining by means of a metal integral connection) may involve selecting the joining point from the plurality of joining points in a manner adapted to the topography of the electrical circuit.

Preferably after the joining step 1104 and/or before the contacting step 1106, the method 1100 may further comprise a step of shortening, for example by milling, the at least one heat transfer module 120. As a result, the contact surface 144 for thermally contacting the relevant heat discharge point 142 can be produced at the second end 124 of the relevant heat transfer module 120 in accordance with the position and/or orientation of the heat discharge point 142.

For example, a plurality of heat transfer modules 120 may be milled in one operation according to the topography of the electrical circuit after joining the plurality of heat transfer modules 120. Due to the mechanical connection of the heat transfer modules 120 via the heat sink 110 that already exists during this operation, the heat transfer modules 120 can be precisely adapted to the height profile of the heat discharge points of the electrical circuit.

Providing 1102 the heat sink 110 may include extruding (e.g., extrusion molding) the heat sink, for example including the heat sink base 114 and the cooling fins 112 and/or including the one or more joining points (i.e., the second profile).

The method 1100 may further involve providing (e.g. extruding, preferably extrusion molding) the at least one heat transfer module 120, for example including the first profile at the first end 122 for press fitting and/or including the contact surface 144 at the second end 124, which is configured to come into contact with a heat discharge point 142 of the electrical circuit in order to absorb the heat of the electrical circuit.

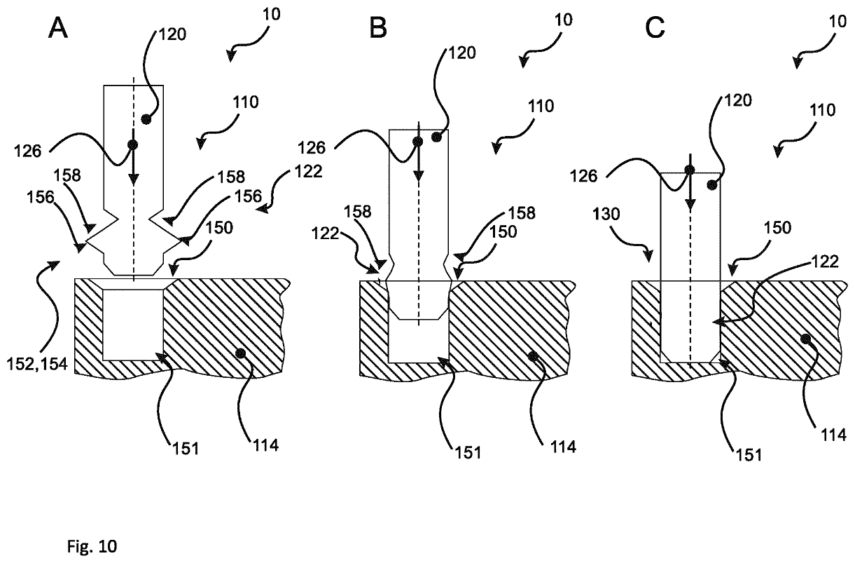

FIG. 10A-C show schematic representations of a further exemplary embodiment of a device according to the invention that is not to scale, wherein different stages of a press-joining process are shown, by means of which a further embodiment of a production process is also illustrated.

FIG. 10A is a schematic view of a first stage of press-joining the heat sink base 114 of the heat sink 110 of a further exemplary embodiment of a device 10 according to the invention, which is partially shown in cross section, with the heat transfer module 120. For the sake of clarity, the reference signs in the illustrations in FIG. 10A-C are sometimes representatively provided in one illustration.

In this first stage, the heat transfer module 120 is spaced apart from the heat sink base 114 and aligned with a joining point 150 provided for the press fit 130 (indicated by a reference sign in FIG. 10C).

Before being inserted into a joining point 150 provided therefor, the first free end 122 of the heat transfer module 120 is designed and configured such that the first free end 122 is elastically-plastically shaped, in particular plastically shaped, at least in portions when inserted into the joining point 150 in order to realize the press fit 130.

This ensures that the free end 122 substantially approximately assumes the cross-sectional shape 151 of the joining point 150 and fills it with few or no gaps for the purposes of thermal contact, as is illustrated by FIG. 10B and FIG. 10C. This makes it possible to realize a press fit 130 with little or no cavities for the purpose of thermal contact, whereby the thermal contact between the heat sink 110 and the heat transfer module 120 is or can be optimized.

In this exemplary embodiment, the elastic-plastic or plastic deformation occurs in particular at the free end 122 of the heat transfer module 120.

For this purpose, prior to its insertion into the joining point 150, the free end 122 has a cross section 152 with a cross-sectional contour 154 which, in this exemplary embodiment, has an arrangement of adjacent projections 156 and depressions 158 in the longitudinal direction 126 (each provided with a consistent reference sign in FIG. 12A/B). Due to the cross-sectional view, the illustration is planar. However, in this exemplary embodiment, the projections 156 and depressions 158 also extend into the plane of the drawing so that, for example, the by each depression 158 has a groove-shaped extension. The same applies to each projection 156 in the sense of a rib-shaped extension.

These (156,158) are arranged adjacently to one another in the longitudinal direction 126 in such a way that during insertion by the aforementioned deformation, the projection 156 and the depression 158 adjacent thereto in the longitudinal direction 126 approach one another during the aforementioned deformation and the projection 156 is reshaped, causing the depression 158 to be filled, whereby the cross section 152 of the free end 122 of the heat transfer module 120 approximately matches the cross-sectional shape 151 of the joining point 150, as can be seen from the illustrations in FIG. 10B/C.

However, the invention is not limited thereto. The projections 156 and depressions 158 can also or only be formed at the joining point 150 of the heat sink 110 so that they can determine the cross-sectional shape 151 of the joining point 150 of the heat sink 110 and/or the free end 122 of the heat transfer module 120.

According to the invention, this provides, among other things, the advantage that stress in the components during insertion for realizing the desired press fit 130 does not lead to undesirable weakening of the component, e.g. due to the formation of stress cracks. Furthermore, the pressing forces can be minimized.

FIG. 10B shows a schematic representation of an intermediate stage in which the free end 122 of the heat transfer module 120 is partially inserted into the joining point 150 of the heat sink 110.

FIG. 10C shows a schematic representation of a final stage in which the free end 122 of the heat transfer module 120 is inserted into the joining point 150 to realize the desired press fit 130. According to the invention, a plurality of joining points 150 or free ends 122 of the heat transfer module 120 can be provided for connecting the heat transfer module 120 and the heat sink to one another, which can have different shapes and therefore do not have to follow a consistent shape. For example, the joining points can have different depths. Furthermore, it is possible for the shapes to be switched so that blind extinguishers can also be formed in the free end 122 of the heat transfer module 120. Furthermore, it is possible to design this so that different shapes alternate and therefore a raised portion follows a recess. Furthermore, the raised portions and recesses can be formed adjacently to one another in a sequence, for example at the free end 122 of the heat transfer module 120 and correspondingly on the heat sink 110.

According to the invention, a heat transfer module 120 or the heat sink 110 with its corresponding shapes (in particular a free end 122 of the heat transfer module 120 as well as the heat sink base 114 of the heat sink 110 or the heat sink as such) for a press-fit or for press-joining/a press-connection can be produced by various manufacturing processes, in particular primary forming processes, for example extrusion or casting, as well as forming processes, such as and in particular extrusion molding.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

10 Conventional device
11 Heat sink of the conventional device
12 Base of the conventional device
13 Circuit board of the conventional device
14 Component on the printed circuit board of the conventional device
15 Component that cannot be mounted in the conventional device
100 Device for cooling an electrical circuit
110 Heat sink
112 Cooling fins of the heat sink, for example lamellae
114 Heat sink base of the heat sink
120 Heat transfer module, for example heat spreader or heat bridge
122 First end of the heat transfer module
124 Second end of the heat transfer module
126 Longitudinal direction
130 Press fit for thermal and mechanical connection between the heat sink and heat transfer module
140 Circuit carrier, for example a printed circuit board, of the electrical circuit
142 Heat discharge point connected via heat transfer module, for example component of the electrical circuit or heat collection point on the circuit carrier
144 Contact surface for thermal contact, for example via thermal paste, also known in technical terms as “Thermal Interface Material” (TIM)
146 Component arranged in space created by heat transfer module
148 Component directly connected to the heat sink
150 Joining point on the heat sink base
151 Cross-sectional shape of the joining point
152 Cross section of the first end of the heat transfer module
154 Cross-sectional contour of the first end of the heat transfer module
156 Projection at the first end of the heat transfer module
158 Sink at the first end of the heat transfer module

1. A device for dissipating heat from an electrical circuit, comprising:
a heat sink having a heat sink base and a plurality of cooling fins extending from the heat sink base configured to discharge heat; and
at least one heat transfer module, which is mechanically and thermally conductively connected or connectable to the heat sink at a first end of the heat transfer module by a press fit and/or a metal integral connection at a joining point of the heat sink, and which has at a second end of the heat transfer module, the second end being at a distance from the first end, a contact surface configured to make contact with at least one heat discharge point of the electrical circuit so as to absorb the heat from the electrical circuit.

2. The device of claim 1, further comprising:
a housing in which the electrical circuit is arranged,
wherein the plurality of cooling fins of the heat sink are exposed outside the housing and/or the at least one heat transfer module is arranged partially or completely within the housing.

3. The device of claim 1, wherein the press fit comprises the metal integral connection at least in regions, and/or
wherein the metal integral connection comprises an arc welded joint, and/or
wherein the press fit comprises the metal integral connection by inductively heating the first end.

4. The device of claim 1, wherein the joining point comprises one cooling fin of the plurality of cooling fins or two adjacent cooling fins of the plurality of cooling fins, and/or
wherein the press fit comprises a friction fit and/or the metal integral connection between the heat transfer module and at least one of the cooling fins of the plurality of cooling fins, of the heat sink.

5. The device of claim 1, wherein the at least one heat transfer module has a first profile of the press fit at the first end, and the heat sink has a second profile at each joining point that complements the first profile, at least in portions.

6. The device of claim 1, wherein the second end is opposite the first end in at least one of the at least one heat transfer modules, and/or
wherein the at least one heat transfer module extends in a longitudinal direction from the second end to the first end and one or more further contact surfaces configured to absorb the heat is or are arranged laterally to the longitudinal direction and/or
wherein the at least one heat transfer module has a plurality of contact surfaces for absorbing the heat.

7. The device of claim 1, wherein the heat sink is independent of the electrical circuit, and/or
wherein the at least one heat transfer module is connected to the heat sink and/or shaped based on a topography of the at least one heat discharge point of the electrical circuit.

8. The device of claim 1, wherein the at least one heat transfer module comprises a plurality of heat transfer modules, each heat transfer module of the plurality of heat transfer modules extending from the heat sink with different lengths between the first end and the second end.

9. The device of claim 1, wherein the heat sink comprises at least one of aluminum, copper, and an alloy, at least in portions, and/or
wherein the at least one heat transfer module comprises at least one of copper, aluminum, and an alloy, at least in portions.

10. The device of claim 1, further comprising:
a component is arranged on a circuit carrier between the electrical circuit and the heat sink base of the heat sink and/or next to the at least one heat transfer module, which component is higher in a direction of the heat sink than the heat discharge point that is contacted via the at least one heat transfer module.

11. The device of claim 1, wherein the at least one heat transfer module comprises a heat pipe containing fluid that is aligned in parallel with a heat flow or a longitudinal direction of the at least one heat transfer module from the second end to the first end.

12. A system, comprising:
the electrical circuit,; and the device of claim 1,
wherein the contact surface of the at least one heat transfer module makes contact with the at least one heat discharge point of the electrical circuit so as to absorb the heat from the electrical circuit.

13. An ensemble, comprising:
a plurality of the device of claim 1,
wherein the plurality of devices of the ensemble each comprise a same heat sink, and
wherein the plurality of devices of the ensemble each differ in that the at least one heat transfer module is mechanically and thermally conductively connected to the heat sink at different joining points of the heat sink and/or that the at least one heat transfer module has different lengths between the first end and the second end.

14. A kit of parts for a device for dissipating heat from an electrical circuit, comprising:
one or more identical heat sinks, which or each of which has or have a heat sink base and a plurality of cooling fins extending from the heat sink base for discharging heat; and
a plurality of heat transfer modules, each heat transfer module of the plurality of heat transfer modules being mechanically and thermally conductively connected to the heat sink at a first end of the heat transfer module by a press fit and/or metal integral connection at a joining point of the heat sink,
wherein each heat transfer module has at a second end of the heat transfer module, the second end being at a distance from the first end, a contact surface configured to make contact with at least one heat discharge point of the electrical circuit so as to absorb heat from the electrical circuit, and
wherein the plurality of heat transfer modules has different lengths between the first end and the second end.

15. A method for producing a device for dissipating heat from an electrical circuit, comprising:
providing a heat sink having a heat sink base and a plurality of cooling fins extending from the heat sink base so as to discharge heat;
press-joining and/or joining at least one heat transfer module with a first end of the at least one heat transfer module at a joining point of the heat sink by a metal integral connection so as to mechanically and thermally conductively connect it to the heat sink; and
bringing the at least one heat transfer module into contact with a contact surface arranged at a second end of the at least one heat transfer module that is at a distance from the first end at at least one heat discharge point of the electrical circuit so as to absorb the heat from the electrical circuit.

16. The device of claim 4, wherein the press fit comprises the metal integral connection between the heat transfer module and the two adjacent cooling fins of the plurality of cooling fins of the heat sink.

17. The device of claim 5, wherein the heat sink comprises one or more further joining points comprising the second profile, and/or
wherein the first profile and the second profile interlock or flow into one another in the press fit.

18. The device of claim 17, wherein the first profile and the second profile interlock or flow into one another without any gaps.

19. The device of claim 6, wherein the one or more further contact surfaces is or are arranged in parallel with the longitudinal direction.

20. The device of claim 8, wherein each heat transfer module of the plurality of heat transfer modules extends from the heat sink with different lengths between the first end and the second end in parallel with one another.
